(19) United States
(12) Patent Application Publication
(10) Pub. No.: US 2024/0040937 A1
(43) Pub. Date: Feb. 1, 2024

(54) METHOD OF PRODUCING AN ELECTRONIC DEVICE PRECURSOR

(71) Applicant: Paragraf Limited, Somersham (GB)

(72) Inventors: Rosie BAINES, Somersham (GB); Lok Yi LEE, Somersham (GB); Hugh GLASS, Somersham (GB)

(73) Assignee: Paragraf Limited, Somersham (GB)

(21) Appl. No.: 18/268,567

(22) PCT Filed: Dec. 17, 2021
(86) PCT No.: PCT/EP2021/086642

§ 371 Date: Jun. 20, 2023

(30) Foreign Application Priority Data
Dec. 18, 2020 (GB) 2020131.5
May 28, 2021 (GB) 2107674.0
Jun. 23, 2021 (GB) 2109011.3

(51) Int. Cl. H10N 52/01; H10N 52/85; H10N 52/00

(52) U.S. Cl. CPC H10N 52/01; H10N 52/85; H10N 52/101

(57) ABSTRACT

There is provided a method 100 of producing an electronic device precursor 200, the method 100 comprising: (i) providing 105 a plasma-etchable layer structure 210 on a plasma-resistant substrate 205, wherein the layer structure 210 has an exposed upper surface; (ii) patterning 110 a plasma-resistant dielectric 215 onto the exposed upper surface to form an intermediate having at least one covered region and at least one uncovered region of the layer structure 210; (iii) subjecting the intermediate to plasma etching 115, whereby the at least one uncovered region of the layer structure 210 is etched away to form at least one covered region of the layer structure 210 having an exposed edge surface; (iv) forming 120 an ohmic contact 220a, 220b in direct contact with a portion of the exposed edge surface; wherein the plasma-etchable layer structure 210 comprises one or more graphene layers which extend across the covered regions of the layer structure 210 to the exposed edge surface.

The present invention provides a method of producing an electronic device precursor. In particular, a method which comprises plasma etching to expose an edge surface of a graphene layer for direct contact with an ohmic contact and forming said ohmic contact. Further, the present invention provides electronic device precursors, in particular electronic device precursors which comprise a graphene layer in direct contact at an edge portion with an ohmic contact. Moreover, the electronic device precursor comprises a continuous air-resistant coating layer to protect the edges of the graphene layer. Most preferably, the electronic device precursor is for a Hall-effect sensor.

Two-dimensional (2D) materials, in particular graphene, are currently the focus of intense research and development worldwide. 2D-materials have been shown to have extraordinary properties, both in theory and in practice which has led to a deluge of products incorporating such materials which include coatings, batteries and sensors to name but a few. Graphene is most prominent and is being investigated for a range of potential applications. Most notable is the use of graphene in electronic devices and their constituent components and includes transistors, LEDs, photovoltaic cells, Hall-effect sensors, diodes and the like.

Accordingly, there are a wide range of electronic devices known in the prior art which have integrated graphene layer structures (single layer or multi-layer graphene) and/or other 2D-materials as key materials for delivering improvements in such devices over earlier devices and electronic products. These include structural improvements through the use of thinner and lighter materials (which can give rise to flexible electronics) as well as performance improvements such as increased electrical and thermal conductance leading to greater operating efficiencies.

However, due to the sensitivity of exposed 2D-materials to atmospheric interaction and contamination, it is necessary to encapsulate the 2D-material and/or the device comprising such materials with a protective layer or layers. The inventors have found that the metal present in ohmic contacts, necessary for forming electrical connections to the 2D-material, can result in undesirable doping. Doping of 2D-materials results in a modification of the electronic properties. For devices such as Hall-effect sensors (also known as Hall-sensors), device operation is highly sensitive to the change in electronic structure due to the reliance on maintaining as close to charge neutrality in the 2D-material as possible. Nevertheless, contamination from oxygen or water vapour in the atmosphere can lead to a degradation in device performance over time which is undesirable for customers/consumers who expect electronic devices to maintain a specified level of performance for many years after manufacture. Moreover, it can be impossible, or at least very difficult, to retrospectively replace electronic components, particularly microelectronic components and as such, even minor improvements in lifetime and performance stability are highly valued.

During manufacture of electronic devices, the inventors have found that standard lithographic processes, such as those which use polymer coatings, such as PMMA, to etch desired configurations of the underlying 2D-material have a number of drawbacks. The PMMA coating can dope the 2D-material and may not be suitable for variable temperature applications or specifically high or low temperature applications. Standard processing to remove such polymer coatings through dissolution in an organic solvent may further introduce impurities and contamination impeding reliable device production with consistent properties which is essential for electronic devices such as microelectronics. It is also known that polymer residues may nevertheless remain, hindering subsequent processing steps.

Alternatively, it is known that 2D-materials may simply be laser etched from a substrate without the use of such photolithographic materials so as to avoid contamination. Such methods comprise using a laser beam to ablate the substrate and 2D-material outside of the active area to leave a patterned 2D-material layer. One such disclosure may be found in GB 2570124 A which discloses using a laser having a wavelength in excess of 600 nm and a power of less than 50 Watts to selectively ablate graphene from a substrate having a thermal resistance greater than that of sapphire. This process has been found to work well at patterning without damaging the graphene layer structure or the underlying substrate but the process can produce large particles of debris which can land on the 2D-material surface. The debris acts as a contaminant or at least prevents the formation of an effective and/or hermetic coating on the 2D-material.

Accordingly, it is desirable to produce electronic devices comprising 2D-materials (or indeed to produce an electronic device precursor for use as an electronic device upon providing the required electrical connections) via methods which involve fewer processing steps thereby avoiding unnecessary and detrimental contamination and/or doping. Consequently, so too is there a desire for electronic devices and their precursors which provide long-term stability and/or improvements in temperature stability over the prior art. Improvements are required to allow use of 2D-material based devices under extreme conditions in order to benefit from the unique electronic properties of the 2D-material.

The inventors have also found that contact deposition after device encapsulation prevents the metal from making electrical contact with the 2D-material which is essential for the final electronic device to function. However, contact deposition before an encapsulation or coating layer can cause problems due to the difference in height between the 2D-material and the contacts thereon leading to a non-conformal coating which may be damaged more easily.

CN 103985762 discloses an ultralow ohmic contact resistance graphene transistor. The method disclosed therein comprises patterning a dielectric layer with a photoresist and etching the dielectric layer using wet chemistry techniques (e.g. buffered oxide etch (BOE) or a mixture of nitric acid and hydrogen peroxide (HNO₃+H₂O₂)).

“The Dependence of the High-Frequency Performance of Graphene Field-Effect Transistors on Channel Transport Properties”, Asad et al. Journal of the Electron Devices Society, 8, 2020, 457-464 discloses a graphene filed effect transistor comprising an Al₂O₃ dielectric layer patterned using lithography techniques and etching to remove the dielectric in the contacts areas on the graphene.

There remains a need for a method which allows for the production of an electronic device precursor that comprises a 2D-material layer, and which avoids surface contamination as well as doping by the ohmic contact deposition. There also remains a need for a method capable of encapsulating the 2D-material whilst also allowing for the provision of at least one ohmic contact. It is an object of the present invention to provide a method and a number of specific embodiments, each of which, along with the electronic device precursors obtainable by such methods, overcome, or substantially reduce, the various problems associated with the prior art or at least provide a commercially useful alternative.

Accordingly, the inventors devised a method which comprises protecting a graphene layer on a substrate using a plasma-resistant dielectric to both define an etching pattern of the graphene layer and serve as a protective coating in the final device precursor (and of course ultimately in a device). The inventors have found that by using a plasma-resistant dielectric to define the etching pattern of the plasma-etchable layer structure comprising graphene, this provides an intermediate which leaves only the edges of the graphene layer exposed and an ohmic contact may be formed in direct contact with a portion of the exposed edge.

Thus, according to a first aspect of the present invention, there is provided a method of producing an electronic device precursor, the method comprising:
(i) providing a plasma-etchable layer structure on a plasma-resistant substrate, wherein the layer structure has an exposed upper surface;
(ii) patterning a plasma-resistant dielectric onto the exposed upper surface to form an intermediate having at least one covered region and at least one uncovered region of the layer structure,
(iii) subjecting the intermediate to plasma etching, whereby the at least one uncovered region of the layer structure is etched away to form at least one covered region of the layer structure having an exposed edge surface;
(iv) forming an ohmic contact in direct contact with a portion of the exposed edge surface,
wherein the plasma-etchable layer structure comprises one or more graphene layers which extend across the covered regions of the layer structure to the exposed edge surface.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The method disclosed herein therefore uses a plasma-resistant dielectric to define an etching pattern and protect the surface of the 2D-material from being doped by the ohmic contact. This solution is particularly elegant since the inventors have found that charge injection is significantly greater at the edges of a 2D-material layer than on the surface, thereby avoiding doping and simultaneously allowing for improved current flow.

As described above, the present invention provides a method of producing an electronic device precursor. A precursor is intended to refer to a component which is capable of being installed into an electrical or electronic circuit, typically by wire bonding to further circuitry or by other methods known in the art such as soldering using “flip chip” style solder bumps as described herein. Thus an electronic device is a functioning device which provides current to the precursor when installed and during operation.

The method comprises a first step of providing a plasma-etchable layer structure on a plasma-resistant substrate, wherein the layer structure has an exposed upper surface and wherein the plasma-etchable layer structure comprises one or more graphene layers.

The plasma-etchable layer structure is one which may be etched during the step of plasma etching as is typical in electronic device fabrication so as to ablate the layer structure and not the underlying substrate. Plasma etching is described in greater detail herein. In the present invention, the plasma-etchable layer structure comprises and preferably consists of one or more graphene layers. Preferably, at least an uppermost layer of the plasma-etchable layer structure is a graphene layer thereby ensuring that at least the uppermost graphene layer is etched during plasma etching to form an exposed edge surface.

Preferably, the plasma-etchable layer structure consists of one or more 2D-material layers. 2D-materials are well known in the art and are sometimes referred to as single layer materials consisting of a single layer of atoms though materials known generally as transition metal dichalcogenides are also well known 2D-materials comprising a layer of metal atoms sandwiched between layers of chalcogen atoms (i.e. a compound of the type MX 2 composed of three atomic planes). Similarly, graphane (CH) n and graphene oxide are 2D-materials, graphane having terminal hydrogen atoms and graphene oxide having bridging oxygen atoms and terminal hydroxyl groups.

Silicene is puckered rather than being perfectly flat. In all circumstances, 2D-materials may be viewed as sheets or layers of quasi infinite size in two-dimensions and include, for example, graphene, graphyne, silicene, germanene, borophene, phosphorene, antimonene, hexagonal boron nitride (h-BN), borocarbonitrides, and TMDCs (such as MoS₂, WS₂, MoSe₂, WSe₂ and MoTe₂). Thus, in some embodiments, the plasma-etchable layer structure consists of one or more layers of graphene and one or more layers of silicene, germanene, h-BN, borophene and/or a TMDC. In such embodiments, the plasma-etchable layer structure may be referred to as a heterostructure. Even more preferably, the plasma-etchable layer structure consists of one or more layers of graphene, which may be referred to as a graphene layer structure.

The present invention provides at least one ohmic contact in direct contact with the exposed edge surface of the at least one graphene layer of the plasma-etchable layer structure. The plasma-etchable layer structure comprises graphene and, optionally, silicene, germanene, borophene, h-BN and/or a TMDC. Accordingly, any reference to graphene herein applies equally to other 2D-materials unless the context clearly dictates otherwise.

The layer structure may comprise from 1 to 10 layers of individual 2D-material layers wherein at least one is a graphene layer. For example, the plasma-etchable layer structure consists of a graphene monolayer. Where the layer structure comprises multiple 2D-material layers, 2 to 5 layers are preferred, and 2 or 3 layers are even more preferable. A single layer is nevertheless also preferred since some of the unique properties attributable to 2D-materials are most pronounced when provided as a monolayer. For example, monolayer graphene is a zero band gap semiconductor (i.e. a semi-metal) wherein the density of states at the Fermi level is zero and lies and the point where the top of the valence band meets the bottom of the conduction band (forming a Dirac cone). Due to the low density of states near the Dirac point, a shift in the Fermi level is particularly sensitive to charge transfer into such pristine graphene. The electronic structure also gives rise to, for example, the quantum Hall-effect. For certain embodiments, especially the Hall-sensor configurations described herein, a graphene monolayer is therefore particularly preferable and benefits greatest from the present invention. Nevertheless, bi-layer or multi-layer graphene (a so-called graphene layer structure) may be used.

In the first step of the method, providing the graphene of the plasma-etchable layer structure may be achieved by any method known in the art. However, the plasma-etchable layer structure, which includes graphene, is synthesised directly on the surface of the substrate and therefore does not involve any physical transfer steps. Preferably the graphene, and any other 2D-material layers, are formed by CVD or MOCVD growth. It is particularly preferable that the graphene is formed by VPE or MOCVD. MOCVD is a term used to describe a system used for a particular method for the deposition of layers on a substrate. While the acronym stands for metal-organic chemical vapour deposition, MOCVD is a term in the art and would be understood to relate to the general process and the apparatus used therefor and would not necessarily be considered to be restricted to the use of metal-organic reactants or to the production of metal-organic materials but would simply require the use of a carbon containing precursor when forming graphene. Instead, the use of this term indicates to the person skilled in the art a general set of process and apparatus features. MOCVD is further distinct from CVD techniques by virtue of the system complexity and accuracy. While CVD techniques allow reactions to be performed with straight-forward stoichiometry and structures, MOCVD allows the production of difficult stoichiometries and structures. An MOCVD system is distinct from a CVD system by virtue of at least the gas distribution systems, heating and temperature control systems and chemical control systems. An MOCVD system typically costs at least 10 times as much as a typical CVD system. MOCVD is particularly preferred for achieving high quality graphene layer structures.

MOCVD can also be readily distinguished from atomic layer deposition (ALD) techniques. ALD relies on step-wise reactions of reagents with intervening flushing steps used to remove undesirable by products and/or excess reagents. It does not rely on decomposition or dissociation of the reagent in the gaseous phase. It is particularly unsuitable for the use of reagents with low vapour pressures such as silanes, which would take undue time to remove from the reaction chamber. MOCVD growth of graphene is discussed in WO 2017/029470 which is incorporated by reference and provides the preferred method.

The method of WO 2017/029470 provides a chamber which has a plurality of cooled inlets arranged so that, in use, the inlets are distributed across the substrate and have a constant separation from the substrate. The flow comprising a precursor compound may be provided as a horizontal laminar flow or may be provided substantially vertically. Inlets suitable for such reactors are well known and include Planetary and Showerhead® reactors available from Aixtron®. Other suitable growth chambers include Turbodisc K-series or Propel® MOCVD systems available from Veeco® Instruments Inc.

Accordingly, in one particularly preferred embodiment, the step of providing a plasma-etchable layer structure on a plasma-resistant substrate is a step of forming a graphene layer structure comprising:
providing the plasma-resistant substrate on a heated susceptor in a reaction chamber, the chamber having a plurality of cooled inlets arranged so that, in use, the inlets are distributed across the substrate and have a constant separation from the substrate,
supplying a flow comprising a precursor compound through the inlets and into the reaction chamber to thereby decompose the precursor compound and form the graphene on the substrate,
wherein the inlets are cooled to less than 100° C., preferably from 50° C. to 60° C., and the susceptor is heated to a temperature of at least 50° C. in excess of a decomposition temperature of the precursor.

Such a method allows for the production of exceptionally high quality, pristine graphene which is scalable for large area substrates and the production of an array of electronic device precursors. As described herein, such pristine graphene is advantageous for use in Hall-sensor applications due the resulting quantum Hall-effect resulting from pristine graphene's unique electronic structure.

As described herein sapphire and silicon are preferred substrates, particularly for graphene prepared by the method of WO 2017/029470. As will be appreciated, a silicon substrate may include a CMOS substrate which is a silicon based substrate whereby graphene is deposited on a silicon surface, though a CMOS substrate may include various additional layers or circuitry embedded therein.

Sapphire is a particularly preferred substrate. R-plane sapphire is most preferred. As is known in the art, r-plane refers to the crystallographic orientation of the surface of the substrate (i.e. the surface upon which graphene is deposited). Such a substrate is particularly suited to providing high quality graphene, most notably sensors such as Hall-effect sensors as described herein. In part, this is due to effect of the substrate on the resulting charge carrier density of the graphene deposited thereon. The inventors have found that r-plane sapphire provides graphene with a particularly low charge carrier density. Preferably, the charge carrier density of the one or more graphene layers is less than 10¹² cm⁻², preferably less than 8×10¹¹ cm⁻². For example, when using r-plane sapphire, a charge carrier density of less than 6×10¹¹ cm⁻² may be obtained, preferably less than 5×10¹¹ cm⁻².

The 2D-material of the plasma-etchable layer structure may be a doped 2D-material. By way of example only, where the 2D-material is graphene and is doped, the graphene is preferably doped with one or more elements selected from the group consisting of silicon, magnesium, zinc, arsenic, oxygen, boron, bromine and nitrogen. Likewise, the method may then preferably comprise introducing a doping element into the reaction chamber and selecting a temperature of the substrate, a pressure of the reaction chamber and a gas flow rate to produce a doped graphene. Preferably, the precursor for doped graphene growth includes the doping element. Alternatively, the precursor comprising the species (which, for example, is carbon for graphene growth and silicon for silicene growth) and one or more further precursors comprising the doping element are introduced to the substrate within the reaction chamber; the second precursor being a gas or suspended in gas, to produce a doped graphene. Deposition of a plasma-resistant dielectric may itself result in doping of the 2D-material. Accordingly, provision of a doped 2D-material can be used to compensate for any doping effect from patterning thereon a dielectric.

The plasma-etchable layer structure is provided on a plasma-resistant substrate. In other words, the layer structure is directly on the substrate without an intervening layer. The layer structure being comprised of 2D-material layers provides the layer structure with two opposing surfaces, a first or lower surface is the surface in direct contact with the substrate. A second or upper surface is therefore exposed and, preferably, at least this layer is a graphene layer.

Plasma-resistant substrates are well known in the art. Ceramic materials such as silicon carbide, silicon nitride and silicon oxide are particularly plasma resistant. Standard crystalline silicon wafers may be considered ceramic and are plasma resistant. Crystalline III-V semiconductors are also plasma-resistant and may be preferable as substrates for specific applications such as LEDs. In a preferred embodiment, the plasma-resistant substrate is sapphire, silicon, silicon dioxide, silicon nitride, silicon carbide, germanium, or a III-V semiconductor, even more preferably sapphire or silicon.

In a preferred embodiment, the rate of etching the layer structure and the substrate differ by at least a factor of 10, preferably, 10² and even more preferably 10³. Thus, regardless of the specific resistivity of the substrate to a given plasma treatment, the layer structure is etched significantly more quickly than the substrate resulting in a complete etch of the exposed layer structure and negligible loss of the substrate surface over the time required for the plasma etch.

Preferably, the plasma-etchable layer structure has an etching rate of greater than 0.345 nm per minute. Plasma etching rate may be measured using oxygen plasma etching with 40 W power and 6 sccm flow of O₂. Therefore, one graphene monolayer (with an ideal thickness of 0.345 nm) will be etched under these conditions in one minute. Preferably, the etching rate is greater than 0.5 nm per minute. Accordingly, the plasma-resistant substrate may preferably have an etching rate of less than nm per minute, preferably less than 0.01 nm per minute.

The method further comprises a step of patterning a plasma-resistant dielectric onto the exposed upper surface to form an intermediate having at least one covered region and at least one uncovered region of the layer structure. As described herein with respect to the plasma-resistant substrate, a plasma-resistant dielectric may be any known in the art and its plasma resistivity measured by the same parameter (i.e. with respect to the layer structure and/or an etching rate). Typically, this will be an inorganic dielectric (i.e. one which does not comprise a carbon-hydrogen bond) such as a ceramic. A ceramic may be considered to be an inorganic oxide, nitride, carbide, fluoride or sulfide and often has a crystalline structure. In a preferred embodiment, the plasma-resistant dielectric is an inorganic oxide, nitride, carbide, fluoride or sulphide and is preferably one of alumina (aluminium oxide), silica (silicon dioxide) or silicon nitride.

Inorganic dielectrics are particularly preferred, especially ceramic dielectrics since these provide significantly improved barrier properties over organic dielectric materials such as PMMA. Thus, the dielectric layer may be retained in the final electronic device precursor to provide protection for the layer structure from contamination from atmospheric contaminants, particularly oxygen and water vapour. This air and moisture resistant coating provides a barrier to unintentional doping over a significantly greater period of time leading to improved device lifetime. Furthermore, inorganic materials such as ceramics can withstand wide temperature fluctuations as well as operation at very high temperatures and permit the use of the electronic device under more extreme conditions without risk of damage and eventual contamination of the layer structure which would otherwise, in time, lead to a drift in device performance (which could require recalibration or simply result in device failure).

The plasma-resistant dielectric is patterned onto the exposed upper surface of the plasma-etchable layer structure. That is, the plasma-resistant dielectric is patterned simultaneously with being deposited on the exposed upper surface of the plasma-etchable layer structure. As described herein, it is particularly preferred that this is achieved by physical vapour deposition (PVD). PVD is a well-known technique. Patterning results in the formation of the dielectric across a portion of the surface thereby forming one or more covered regions and one or more uncovered regions of the layer structure (providing an intermediate in the manufacture of the device precursor). In a preferred embodiment, the method comprises forming an array of covered regions, each corresponding to an electronic device precursor. Such a patterning to form an array of covered regions may comprise using a mask (i.e. a shadow mask) to thereby form the dielectric in a plurality of regions. The formation of at least one covered region results in the uncovered regions being the remainder of the layer structure. Accordingly, where an array of covered regions are patterned on the layer structure, this typically affords at least a single continuous uncovered region separating the covered regions. In a preferred embodiment, only one uncovered region is formed during the patterning step since the step of plasma etching as described herein then results in the formation of a continuous outer edge surface of the layer structure for each electronic device precursor (i.e. the formation of a “filled” “2D shape” with an outer edge). However, in some embodiments, the 2D shaped and patterned dielectric may have an uncovered portion therein providing an inner and outer edge to the graphene layer after etching.

Accordingly, in a preferred embodiment, the patterning step comprises forming one or more rectangular-shaped regions of the plasma-resistant dielectric. Such a patterning of the dielectric, and subsequently the 2D-material, means the electronic device precursor is particularly preferable for forming a transistor. The electronic device precursor may then preferably further comprise a third contact, a gate contact. A gate contact may be provided, for example, on top of the plasma-resistant dielectric or the coating (when present) as a so-called “front gate”, or alternatively on the underside of the substrate as a so-called “back-gate”. When provided on the underside of the substrate, the 2D-material is provided on an insulating region of the substrate surface. SiO₂, SiO₂/Si and silicon substrates with “buried” SiO₂ regions (as well as silicon nitride equivalents) are exemplary substrates which may be used to manufacture the transistor of the present invention. Alternatively, in a preferred embodiment, the patterning step comprises forming one or more regions with “Hall-bar” and/or “van der Pauw” geometries (such geometries or shapes are well known in the art and include, for example, a circle, “clover leaf”, square, rectangle and cross), preferably cross-shaped regions, of the plasma-resistant dielectric. These geometries are well known in the art for Hall-sensors (which require at least 4 contacts), the cross being the most preferred geometry and thus, the electronic device precursor is preferably for forming a Hall-sensor.

In embodiments which comprise forming an array of covered regions, the method preferably further comprises a step of dicing the substrate to separate electronic device precursors from the array. Thus, a plurality of electronic device precursors may be manufactured simultaneously on a single substrate and subsequently diced for individual use. This dicing step is preferably performed towards the end of the process.

In a preferred embodiment of the present invention, the step of patterning comprises patterning the plasma-resistant dielectric by physical vapour deposition such as e-beam evaporation or thermal evaporation. Preferably, e-beam evaporation is used to pattern the plasma-resistant dielectric and preferably performed using a mask (i.e. a shadow mask). Such a method is particularly suitable for the deposition of an alumina or silica plasma-resistant dielectric layer on 2D-material layers.

Preferably, the thickness of the patterned dielectric is less than 200 nm, preferably less than 100 nm, more preferably less than 50 nm and/or greater than 1 nm, preferably greater than 3 nm, more preferably greater than 5 nm. Accordingly, the dielectric layer may have a thickness of between 1 nm and 200 nm, preferably between 3 nm and 100 nm and even more preferably between 5 nm and 50 nm.

The method further comprises subjecting the intermediate to plasma etching, whereby the at least one uncovered region of the layer structure is etched away to form at least one covered region of the layer structure having an exposed edge surface. The step of plasma etching results in all uncovered regions of the plasma-etchable layer structure being etched thereby exposing the underlying substrate in these regions. The plasma-resistant dielectric prevents etching of the layer structure in the covered regions and therefore, plasma etching results in the formation of an exposed edge of the layer structure, coterminous with the shape of the patterned dielectric thereon. Thus, as described herein, the 2D-material layers extend across (and beneath) the covered regions of the layer structure to the exposed edge surface. Accordingly, the shape or pattern of the dielectric defines the shape of the etched 2D-material layer.

Plasma etching is a typical process used in the manufacture of electronic devices and integrated circuits. Plasma etching involves the flow of a plasma of an appropriate gas mixture across the substrate, the plasma having been formed from application of an RF across two electrodes, typically under low pressure. In oxygen plasma etching, the RF radiation ionises the gas to form oxygen radicals which etch the layer structure. The by-products, also known in the art as “ash”, are removed by a pump which are predominantly carbon monoxide and carbon dioxide when a graphene layer structure is etched by oxygen plasma etching. In a preferred embodiment, the plasma etching comprises oxygen plasma etching. In a preferred embodiment, oxygen plasma etching comprises using at least 5 W RF power, preferably at least 10 W and more preferably at least 20 W, and preferably less than 200 W, preferably less than 100 W. The flow rate of O₂ may be at least 1 sccm, preferably at least 3 sccm and/or less than 50 sccm, preferably less than 30 sccm. Preferably, the chamber pressure is at least 0.1 mbar and/or at most 100 mbar, preferably at least 0.2 mbar and/or at most 10 mbar. Accordingly, the time required for plasma etching may be as little as 1 second and/or up to 5 minutes. Preferably, the time required is at least 10 seconds and/or less than 2 minutes.

Finally, the method of the present invention further comprises a step of forming an ohmic contact (i.e. at least one ohmic contact) in direct contact with a portion of the exposed edge surface. Further contacts may also be formed and may be formed simultaneously. In which case, further contacts are also provided in direct contact with the exposed edge surface but separate to any other contacts (i.e. the contacts are not in contact with one another). Preferably, the one or more ohmic contacts are metal contacts, preferably comprising one or more of titanium, aluminium, chromium and gold.

Preferably, the contacts are titanium and/or gold metal contacts. The contacts may be formed by any standard technique such as electron beam deposition, preferably using a mask.

The inventors have found that not only does the dielectric layer protect the underlying 2D-material from atmospheric contamination but prevents the contacts from forming on the surface of the 2D-material. Therefore, the 2D-material is substantially protected from metal doping since contact is only made at the exposed edge and by avoiding wet lithography techniques, including avoiding etchants such as BOE, an improved contact between the ohmic contact and graphene can be achieved. Furthermore, the inventors have found that charge injection is significantly more efficient at the edge of a 2D-material as a result.

Whilst the protective dielectric layer serves to restrict contamination of the graphene surface and is nevertheless very effective, especially over long periods of time, the inventors have found that the exposed edges can overtime provide a route for contamination and doping of the 2D-material. Whilst this process is significantly slower than surface doping, and may also only occur to a limited extent, the inventors have found that stability and lifetime can be further improved by providing a further protective layer or a coating layer which is air (and moisture) resistant. As described herein for devices such as Hall-sensors, the function of devices based on 2D-materials can be highly sensitive to any changes in charge carrier density (i.e. resulting from doping by contaminants, primarily oxygen and water vapour which are atmospheric contaminants). The inventors have found that devices based on shapes with many edges, such as the cross-shape of a Hall-sensor, are more prone to contamination and therefore benefit greatly from a further coating. Consequently, the method provides more robust devices than those of the prior art.

Accordingly, the method described herein preferably further comprises, either before or after forming the one or more ohmic contacts, a step of forming a coating layer to provide the layer structure (and its patterned dielectric) with a continuous air-resistant coating. The continuous air-resistant coating therefore coats at least the layer structure (comprising the etched 2D-material layers and patterned dielectric) and adjacent regions of the substrate so as to enclose the layer structure and protect all remaining portions of the exposed edge (i.e. all of the edges which are not in direct contact with the ohmic contact). As described herein, the coating layer may be patterned so as to leave a portion of the contact exposed for connection to a circuit. Alternatively, the coating layer may be formed across the substrate coating the entire substrate, all of the layer structure (and edges) and all of the one or more contacts.

The air-resistant coating may be referred to as a hermetic coating. The coating may be characterised by an oxygen transmission rate of less than 10⁻¹ cm³/m²/day/atm, preferably less than 10⁻³ cm³/m²/day/atm and more preferably less than 10⁻⁵ cm³/m²/day/atm. The air-resistant coating may also be characterised by a water vapour transmission rate of less than 10⁻² g/m²/day, preferably less than 10⁻⁴ g/m²/day, more preferably less than 10⁻⁵ g/m²/day. Such transmission rates are generally accepted in the art as necessary for use in electronic devices such as LEDs wherein the more preferred transmission rates are necessary for OLEDs and Hall-sensors.

The inventors have also found that the use of plasma etching to etch the layer structure in the uncoated region(s) is particularly advantageous when combined with the further coating layer. This is due to the plasma etching step not causing deposits to form on the layer structure or substrate and does not affect the substrate surface roughness (for example by pitting) which can result from alternative techniques such as laser etching. This in turn leads to a significant improvement in the properties of coating layer.

Preferably the coating layer is an inorganic oxide, nitride, carbide, fluoride or sulphide, preferably alumina or silica. Preferably, the thickness of the coating layer is greater than 10 nm, preferably greater than 25 nm and more preferably greater than 50 nm. There is no specific upper limit though thicknesses of greater than 10 μm, or greater than 1 μm may only provide limited further protective properties whilst simply increasing the weight and thickness of the device precursor. Additionally, deposition rates by ALD for example can be a slow process and thicker coatings would unduly extend the manufacturing time. Accordingly, an ALD layer thickness of up to 500 nm, preferably up to 100 nm, is also preferable.

The inventors have found different solutions to various problems encountered during the manufacture of such electronic device precursors which comprise a coating layer, each solution as described herein having its own advantages and drawbacks.

One preferred embodiment of the present invention comprises forming the coating layer after the ohmic contact and therefore the ohmic contact is formed on the plasma-resistant substrate. In this embodiment, the coating layer is formed by atomic layer deposition (ALD) across the plasma-resistant substrate to provide the at least one covered region of the layer structure, the ohmic contact, and remaining exposed edge surface with a continuous air-resistant coating.

ALD is technique known in the art and comprises the reaction of at least two precursors in a sequential, self-limiting manner. Repeated cycles to the separate precursors allow the growth of a thin film in a conformal manner (i.e. uniform thickness across the entire substrate) due to the layer-by-layer growth mechanism. Alumina is a particularly preferred coating material and can be formed by sequential exposure to trimethylaluminium (TMA) and an oxygen source, preferably one or more of water (H₂O), O₂, and ozone (O₃), preferably water. ALD is particularly advantageous because a coating may be formed reliably over the entire substrate (i.e. provides a conformal coating). However, the inventors also found that whilst an excellent protective coating layer may be formed by ALD, the full coating can result in problems for dicing where an array of electronic device precursors are manufactured on the substrate. Dicing (or cutting) then necessarily involves dicing through the coating layer to separate the individual device precursors and this process can be susceptible to introducing micro-cracking in the coating layer.

Such a coating layer also coats the entire contact thereby sealing the contact. The inventors have nevertheless found that wire bonding may be used to pierce the coating layer to attach a wire to the contact. Thus, the method preferably comprises wire bonding to the ohmic contacts of the device precursor through the coating layer. Whilst ALD provides a highly uniform protective coating, the coating can be damaged when punctured in order to make the wire bond contact.

Thus, the inventors developed a further preferred embodiment wherein the ohmic contact is still formed before the coating and therefore on the plasma-resistant substrate, however, the coating layer is formed by patterning a coating layer onto the plasma-resistant substrate to provide the at least one covered region of the layer structure and remaining exposed edge surface with a continuous air-resistant coating.

The coating layer is preferably patterned using the same technique described herein with regards to the dielectric patterning. One difference is that the pattern will be geometrically larger so as to cover the exposed edges of the layer structure and therefore the adjacent portion of the substrate as well as a portion of the contact thereby leaving a portion of the contact exposed. Patterning of, for example, alumina, may again be performed using e-beam evaporation.

This embodiment therefore is advantageous since the portions of the substrate between adjacent layer structures of an array (or simply portions of the substrate) remain exposed (and may be referred to as “streets” or “die streets”). Thus the substrate may be diced without the risk of damaging the coating layer. Furthermore, since the contact remains exposed, the contact may be wire bonded without any risk of damage or cracking of the coating layer or alternatively a solder bump may be deposited on the contact.

Unlike the use of ALD to provide a conformal coating over the entire substrate, evaporation is less conformal and risks edges remaining exposed. In particular, e-beam evaporation is directional in that shadows, in particular those created by the contact restrict uniform growth of the coating. It is however known in the art to rotate the substrate during coating to minimise this effect.

A further preferred embodiment instead provides the coating layer before forming the contact and comprises selectively etching away one or more portions of the coating layer to expose corresponding portions of the edge surface. The step of forming a contact then comprises forming an ohmic contact in direct contact with each exposed portion of the edge surface.

The coating layer may therefore be provided by ALD or e-beam evaporation. Since this embodiment involves forming the coating before any ohmic contacts, even better coatings can be achieved, even with e-beam evaporation thereby allowing the streets to remain clear. The inventors have found that the coating need be etched in selective portions to expose the corresponding portions of the underlying edge surface in order to allow the formation of the ohmic contact. The selective etching is preferably performed using laser etching, reactive ion etching (in a so-called “dry etch”), chemical etching (in a so-called “wet etch”) and/or photolithography. Since the 2D-material is substantially protected from contamination, such methods may be used without significant detrimental effects. Nevertheless, laser etching and reactive ion etching are preferable since these are “dry” methods with reduced risk of doping the 2D-material, reactive ion etching being the most preferred. In some embodiments, the selective etching may be performed for a time sufficient to etch away the coating layer to expose the corresponding edge surface of the plasma etchable-layer structure.

This method then requires the formation of the ohmic contact in direct contact with the edge surfaces exposed by the selective etching in each etched portion. This is advantageous since the contact is therefore exposed for connection to an electronic circuit. In particular, the method may further comprise depositing a solder bump (or a solder ball) on the ohmic contact. This allows the electronic device precursor to be used as a so-called “flip chip”. Nevertheless, wire bonding is also preferred. Wire bonding is known in the art and may involve ball bonding, wedge bonding or compliant bonding.

The inventors have however found that this embodiment introduces added complexity in the alignment required for the selective etch and for contact deposition within the selectively etched portion. Etching also nevertheless comes with risks of forming cracks in the coating.

In a second aspect of the present invention, there is provided an electronic device precursor comprising:
a substrate having a layer structure thereon, the layer structure comprising:
   a lower layer on a first region of the substrate, wherein the lower layer comprises one or more graphene layers which extend across the lower layer, and
   an upper layer on the lower layer and formed of a dielectric material,
   wherein the lower and upper layers share a continuous outer edge surface,
an ohmic contact provided on a further region of the substrate and in direct contact with the one or more graphene layers via the continuous outer edge surface, and
a continuous air-resistant coating layer across the substrate, the layer structure, and the at least one ohmic contact.

In a third aspect of the present invention provides an electronic device precursor comprising:
a substrate having a layer structure thereon, the layer structure comprising:
   a lower layer on a first region of the substrate, wherein the lower layer comprises one or more graphene layers which extend across the lower layer, and
   an upper layer on the lower layer and formed of a dielectric material,
   wherein the lower and upper layers share a continuous outer edge surface,
an ohmic contact provided on a further region of the substrate and in direct contact with the one or more graphene layers via the continuous outer edge surface, and
a continuous air-resistant coating layer enclosing the layer structure.

In a fourth aspect of the present invention, there is provided an electronic device precursor comprising:
a substrate having a layer structure thereon, the layer structure comprising:
   a lower layer on a first region of the substrate, wherein the lower layer comprises one or more graphene layers which extend across the lower layer, and
   an upper layer on the lower layer and formed of a dielectric material,
   wherein the lower and upper layers share a continuous outer edge surface,
an ohmic contact in direct contact with the one or more graphene layers via the continuous outer edge surface; and
a continuous air-resistant coating layer enclosing the layer structure.

The electronic device precursor of the further aspects of the invention disclosed herein are preferably obtainable by the method described herein. Accordingly, all features described in relation to the first aspect may be applied equally to the further aspects of the invention as appropriate.

Consequently, the electronic device precursor of the further aspects of the invention share the feature of a layer structure comprising a lower layer comprising one or more graphene layers and an upper layer formed of a dielectric material wherein the lower and upper layers share a continuous outer edge surface. This therefore provides the graphene with excellent protection from atmospheric contamination leading to improved stability of device performance over longer periods of time, and by extension device lifetime.

Furthermore, an ohmic contact is provided for connection to an electronic circuit and the ohmic contact is only in direct contact with the edge of the graphene layer and not the upper (or lower) planar surface. The edge contact provides improved charge injection relative to surface contacts and substantially avoids doping of the graphene. This is particularly useful where the device precursor is intended for use at high temperatures wherein the increased temperature can result in doping of the 2D-material by, for example, the metal of an ohmic contact, after manufacture and during subsequent use.

In a preferred embodiment of the present invention, the electronic device precursor is for a transistor or a Hall-sensor, most preferably a Hall-sensor. Nevertheless, many other electronic devices can be manufactured using the method described herein and/or from the electronic device precursors described herein and include capacitors, diodes and inductors.

In a particularly preferred embodiment of the present invention, the method described herein comprises:
(i) providing a plasma-etchable layer structure on a plasma-resistant substrate, wherein the layer structure has an exposed upper surface;
(ii) patterning a plasma-resistant dielectric onto the exposed upper surface to form an intermediate having at least one covered region and at least one uncovered region of the layer structure;
(iii) subjecting the intermediate to plasma etching, whereby the at least one uncovered region of the layer structure is etched away to form at least one covered region of the layer structure having an exposed edge surface;
(iv) forming an ohmic contact on the plasma-resistant substrate and in direct contact with a portion of the exposed edge surface;
(v) forming a coating layer by ALD across the plasma-resistant substrate to provide the at least one covered region of the layer structure, the ohmic contact, and remaining exposed edge surface with a continuous air-resistant coating;

wherein the plasma-etchable layer structure comprises or consists of one or more graphene layers which extend across the covered regions of the layer structure to the exposed edge surface. Thus, the electronic device precursor of the second aspect described herein is preferably obtainable, even more preferably obtained, by this method.

The device precursor of the second aspect comprises a continuous air-resistant coating layer across the substrate, the layer structure, and the at least one ohmic contact and this may also be regarded as having enclosed the layer structure in accordance with the third and fourth aspects disclosed herein.

In a particularly preferred embodiment of the present invention, the method described herein comprises:
(i) providing a plasma-etchable layer structure on a plasma-resistant substrate, wherein the layer structure has an exposed upper surface;
(ii) patterning a plasma-resistant dielectric onto the exposed upper surface to form an intermediate having at least one covered region and at least one uncovered region of the layer structure;
(iii) subjecting the intermediate to plasma etching, whereby the at least one uncovered region of the layer structure is etched away to form at least one covered region of the layer structure having an exposed edge surface;
(iv) forming an ohmic contact on the plasma-resistant substrate and in direct contact with a portion of the exposed edge surface;
(v) patterning a coating layer onto the plasma-resistant substrate to provide the at least one covered region of the layer structure and remaining exposed edge surface with a continuous air-resistant coating;

wherein the plasma-etchable layer structure comprises or consists of one or more graphene layers which extend across the covered regions of the layer structure to the exposed edge surface. Thus, the electronic device precursor of the third and/or fourth aspect described herein is preferably obtainable, even more preferably obtained, by this method.

In a particularly preferred embodiment of the present invention, the method described herein comprises:
(i) providing a plasma-etchable layer structure on a plasma-resistant substrate, wherein the layer structure has an exposed upper surface;
(ii) patterning a plasma-resistant dielectric onto the exposed upper surface to form an intermediate having at least one covered region and at least one uncovered region of the layer structure;
(iii) subjecting the intermediate to plasma etching, whereby the at least one uncovered region of the layer structure is etched away to form at least one covered region of the layer structure having an exposed edge surface;
(iv) forming a coating layer on the plasma-resistant substrate to provide the at least one covered region of the layer structure and the exposed edge surface with a continuous air-resistant coating;
(v) selectively etching away one or more portions of the coating layer to expose corresponding portions of the edge surface;
(vi) forming an ohmic contact in direct contact with each exposed portion of the edge surface; wherein the plasma-etchable layer structure comprises or consists of one or more graphene layers which extend across the covered regions of the layer structure to the exposed edge surface. Thus, the electronic device precursor of the fourth aspect described herein is preferably obtainable, even more preferably obtained, by this method.

In an even more preferred embodiment of the present invention the method described herein comprises:
(i) providing a monolayer of graphene on a sapphire substrate by MOCVD, wherein the monolayer of graphene has an exposed upper surface;
(ii) patterning alumina as one or more cross-shaped regions onto the exposed upper surface to form an intermediate having at least one covered region and at least one uncovered region of the graphene monolayer;
(iii) subjecting the intermediate to oxygen plasma etching, whereby the at least one uncovered region of the monolayer of graphene is etched away to form at least one covered region of monolayer graphene having an exposed edge surface;
(iv) forming four gold ohmic contacts for every cross-shaped region formed in step (ii) on the sapphire substrate, each contact in direct contact with a distal portion of the exposed edge surface of the four arms of the cross;
(v) forming an alumina coating layer by ALD across the sapphire substrate to provide the at least one covered region of monolayer graphene, the ohmic contacts, and remaining exposed edge surfaces with a continuous air-resistant coating;
wherein the monolayer of graphene extends across the at least one covered region to the exposed edge surface, and the electronic device precursor is for forming a Hall-sensor.

Accordingly, a preferred electronic device precursor is one for a Hall-sensor and comprises:
a sapphire substrate having a layer structure thereon, the layer structure comprising:
   a monolayer of graphene on a first region of the sapphire substrate, and
   an alumina layer on the graphene monolayer,
   wherein the graphene and alumina are cross-shaped and share a continuous outer edge surface,
four gold ohmic contacts, each contact provided on a further region of the sapphire substrate and in direct contact a distal portion of the exposed edge surface of each of the four arms of each cross, and
a continuous alumina coating layer across the sapphire substrate, the layer structure, and the contacts.

In another even more preferred embodiment of the present invention, the method described herein comprises:
(i) providing a monolayer of graphene on a sapphire substrate by MOCVD, wherein the monolayer of graphene has an exposed upper surface;
(ii) patterning alumina as one or more cross-shaped regions onto the exposed upper surface to form an intermediate having at least one covered region and at least one uncovered region of the graphene monolayer;
(iii) subjecting the intermediate to oxygen plasma etching, whereby the at least one uncovered region of the monolayer of graphene is etched away to form at least one covered region of monolayer graphene having an exposed edge surface;
(iv) forming four gold ohmic contacts for every cross-shaped region formed in step (ii) on the sapphire substrate, each contact in direct contact with a distal portion of the exposed edge surface of the four arms of each cross;
(v) patterning an alumina coating layer by e-beam evaporation onto the sapphire substrate to provide the at least one covered region of monolayer graphene and remaining exposed edge surfaces with a continuous air-resistant coating;
wherein the monolayer of graphene extends across the at least one covered region to the exposed edge surface, and the electronic device precursor is for forming a Hall-sensor.

Similarly, in another even more preferred embodiment of the present invention, the method described herein comprises:
(i) providing a monolayer of graphene on a sapphire substrate by MOCVD, wherein the monolayer of graphene has an exposed upper surface;
(ii) patterning alumina as one or more cross-shaped regions onto the exposed upper surface to form an intermediate having at least one covered region and at least one uncovered region of the graphene monolayer;
(iii) subjecting the intermediate to oxygen plasma etching, whereby the at least one uncovered region of the monolayer of graphene is etched away to form at least one covered region of monolayer graphene having an exposed edge surface;
(iv) forming an alumina coating layer on the sapphire substrate to provide the at least one covered region of monolayer graphene and the exposed edge surface with a continuous air-resistant coating;
(v) selectively laser etching four portions of the alumina coating layer to expose corresponding portions of the edge surface of the graphene monolayer so as to expose the distal portions of the edge surface of the four arms of each cross;
(vi) forming four gold ohmic contacts in direct contact with each of the four exposed portions of the edge surface;
wherein the monolayer of graphene extends across the at least one covered region to the exposed edge surface, and the electronic device precursor is for forming a Hall-sensor.

Accordingly, a preferred electronic device precursor is one for a Hall-sensor and comprises:
a sapphire substrate having a layer structure thereon, the layer structure comprising:
   a monolayer of graphene on a first region of the sapphire substrate, and
   an alumina layer on the graphene monolayer,
   wherein the graphene and alumina are cross-shaped and share a continuous outer edge surface,
four gold ohmic contacts, each contact provided on a further region of the sapphire substrate and in direct contact a distal portion of the exposed edge surface of each of the four arms of the cross, and
a continuous alumina coating layer across enclosing the layer structure.

Thus, a preferred electronic device precursor comprises an alumina coating layer which encapsulates the layer structure protecting the edges of the monolayer of graphene. The contact of the device precursor is at least partially exposed, i.e. not coated by the alumina coating layer as is the sapphire substrate at least partially exposed. Typically, at least regions of the substrate between adjacent device precursors as part of an array so as to allow for the dicing of the common substrate to provide a plurality of device precursors without the risk of damaging the coating during the cutting.

In embodiments wherein the coating layer is first deposited then etched to expose the edge surface of the graphene to provide such an electronic device precursor, the contact will be exposed vertically by virtue of having been deposited into a laser etched opening in the coating.

In embodiments wherein the coating layer is patterned after the formation of contacts, partial coating of the contact during patterning may leave an upper surface of the contact exposed. However, it is also possible to pattern the coating layer over the upper surface of the contact and at least an edge surface will be left exposed by the patterning of the coating layer. In other words, the contacts are not fully encapsulated by the coating layer in the final electronic device precursor thereby allowing simple wire bonding or soldering for connection to an electronic circuit without having to puncture the coating layer.

### FIGURES

The present invention will now be described further with reference to the following non-limiting Figures, in which:

FIG. 1 is a flowchart illustrating the method of the present invention.

FIG. 2 is a cross-sectional view of an electronic device precursor in accordance with an embodiment of the present invention.

FIG. 3 is a cross-sectional view of another electronic device precursor in accordance with an embodiment of the present invention.

FIG. 4 is a plan view of another electronic device precursor in accordance with an embodiment of the present invention.

FIG. 5 is a plan view of another electronic device precursor in accordance with an embodiment of the present invention.

FIG. 6 is a perspective view of an array of electronic device precursors in accordance with an embodiment of the present invention.

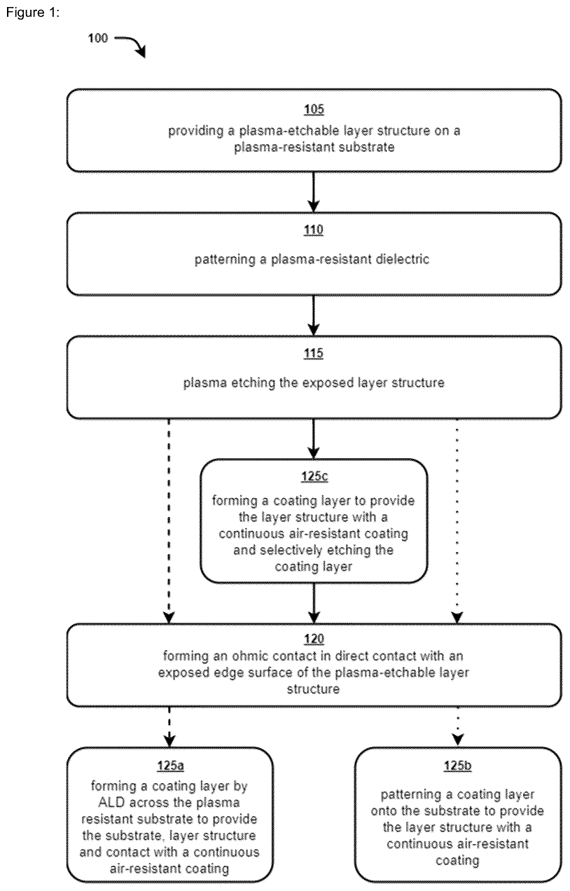

FIG. 1 is a flow chart illustrating the method of the present invention 100. The method 100 comprises a number of essential steps (105, 110, 115 and 120) and may further comprise one of three optional steps (125a, 125b and 125c) representing three alternatively preferred specific embodiments of method 100.

The method 100 is for forming an electronic device precursor suitable for a Hall-sensor and comprises a first step 105 of providing a plasma-etchable layer structure on a plasma-resistant substrate. In exemplary method 100, the plasma-etchable layer structure consists of a graphene monolayer provided by MOCVD directly on a sapphire substrate.

Next, a further step 110 involves patterning an array cross-shaped regions of alumina by e-beam evaporation, onto the exposed upper surface of the graphene monolayer to form an array of intermediates. The method will be further described with reference to one intermediate though it will be appreciated that all of the intermediates of the array are treated simultaneously. Step 115 involves subjecting the intermediate to oxygen plasma etching to thereby etch the exposed graphene monolayer and form an array of cross-shaped regions of graphene covered with alumina, the alumina covered graphene having a continuous exposed edge surface.

Method 100 further comprises a step 120 of forming a metal ohmic contact in direct contact with a portion of the exposed edge surface of the etched graphene monolayer. In particular, four metal contacts are formed at the end of each of the “arms” of the cross-shape.

In a first specific embodiment of method 100, the method 100 further comprises a step 125a, performed after step 120, which comprises forming a coating layer of alumina by ALD across the sapphire substrate thereby coating the alumina coated graphene, the ohmic contacts and the exposed substrate with a continuous air-resistant coating.

In a second specific embodiment, the method 100 further comprises a step 125b, performed after step 120, which comprises patterning an alumina coating layer by e-beam evaporation onto the substrate thereby coating the alumina coated graphene with a continuous air-resistance coating. The alumina coating provided by step 125b therefore coats and protects the exposed edge(s) which are not in contact with the ohmic contact from atmospheric contamination and the pattern of the coating is the same geometric cross-shape, but geometrically larger. For example, the maximum width and/or maximum height of the shape may be 10% larger, or even 20% larger that than of the patterned alumina of step 110. The patterning step also leaves a portion of each metal contact exposed for connection to an electronic circuit.

In a third specific embodiment, the method 100 further comprises a step 125c of forming a coating layer before step 120. Step 125c involves forming a coating layer, to provide the alumina coated graphene monolayer with a continuous air-resistant coating of alumina (i.e. such that the exposed edge surface is coated). In this embodiment, step 120 further involves a step of selectively laser etching four portions of the coating layer at the end of each of the “arms” of the underlying cross-shape to expose the corresponding portions of the edge surface of the graphene. As required by method 100, step 120 then involve forming the metal ohmic contacts in direct contact with the exposed edge surface in each of the selectively etch portions.

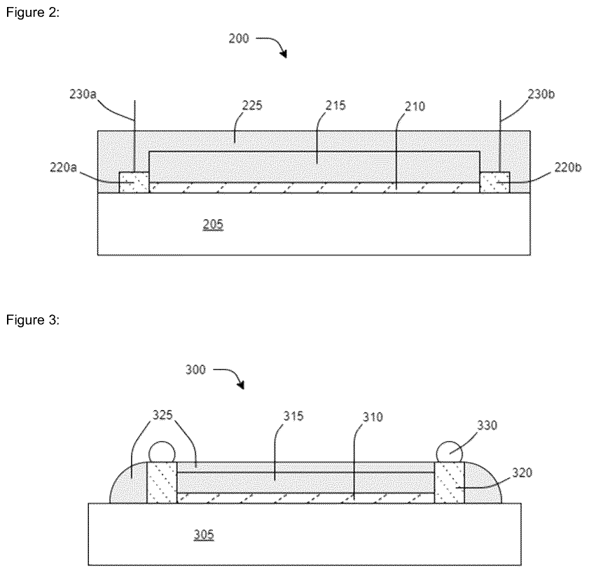

FIG. 2 is a cross-sectional view of an electronic device precursor 200. The precursor 200 is obtainable by the method described herein which involves forming a coating layer by ALD after forming the ohmic contacts.

The electronic device precursor 200 is formed of a sapphire substrate 205 upon which there is a plasma-etchable 2D-material layer 210 comprising a graphene layer structure. The 2D-material layer 210 has a shape defined by the alumina layer 215 formed thereon. Accordingly, the 2D-material layer and the alumina share a continuous edge surface wherein the graphene layer structure extends to this edge.

The precursor 200 further comprises two ohmic contacts 220a and 220b, each in direct contact with said edge of the 2D-material layer 210 and therefore of the graphene layer structure. No contact material is on the surface of the 2D-material layer 210 since the alumina and 2D-material share a continuous edge surface and are of the same shape. Advantageously, the contact does not result in any appreciable doping of the 2D-material as that which may be observed when contacts are provided on the planar surface of a 2D-material. Further, edge contact provides improved charge injection relative to surface charge injection improving overall efficiency (for example by reducing any electrical losses as heat).

A continuous air-resistant coating layer of silica is formed on the alumina coating 215, the contacts 220a and 220b and the substrate 205. The coating 225 provides excellent protection from atmospheric contamination by prevent the ingress of, for example, oxygen gas and water vapour. The precursor 200 further comprises wires 230a and 230b which have been wire bonded to the ohmic contacts 220a and 220b, respectively. The wires 230a and 230b provide a means for electrical connectivity to the ohmic contacts and therefore protrude out of the coating layer.

The inventors have found that the electronic device precursor 200 provides an electronic device with excellent stability. In particular, the inventors have found that a device formed from precursor 200 exhibits a rate of degradation of less than 0.01%/day (as measured with respect to the initial carrier concentration, and therefore sensitivity, of the device and the point of manufacture).

By way of comparison, a device formed from a precursor wherein the coating layer (e.g. coating layer 215) is not provided and instead a ceramic lid, is used to “seal” the components (as is well-known in the art and which may also be used in combination with the present invention), the sensitivity of such a device was found to degrade at a rate in excess of 0.5%/day. Likewise, the inventors found that the absence of a coating layer or ceramic lid was significantly greater still.

By way of further comparison, the inventors found that devices formed using an organic, PMMA, coating layer provided greater protection against degradation over known ceramic lids, such devices having a rate of degradation of between 0.03%/day and 0.1%/day.

The inventors have also found that when metal contacts are deposited on graphene before the patterning of a dielectric layer, the metal results in heavy doping of the graphene of greater than 12 cm⁻² and even greater than 10¹³ cm⁻² thereby significantly reducing sensitivity. FIG. 3 is a cross-sectional view of an electronic device precursor 300. The precursor 300 is obtainable by the method described herein which involves forming a coating layer before the step of forming the ohmic contacts.

The electronic device precursor 300 comprises a sapphire substrate 305 upon which there is a plasma-etchable 2D-material layer 310. In this embodiment, the 2D-material layer consists of bi-layer graphene (i.e. a graphene monolayer having 2 layers of graphene). Formed thereon is a patterned layer of silica 315 which shares a continuous edge surface with the bi-layer graphene 310. Deposited on the surface of the patterned silica layer 315 is a continuous air-resistant coating 325. The coating 325 is also deposited on an adjacent portion of the surface of the substrate 305. FIG. 3 is a cross-section view of precursor 300, the cross-section bisects two ohmic contacts 320 deposited on the substrate 305. It will be appreciated that in alternative cross-sections, the coating layer the coating layer 325 will be continuous.

The contacts 320 are in direct contact with an edge surface of the bi-layer graphene, as well as the silica and alumina coatings thereon. The precursor 300 may be obtained by the method described herein which comprises selectively etching a coating layer formed before forming the ohmic contacts.

Accordingly, the contacts extend from the surface of the substrate 305 which is exposed during the etching process to the surface of the coating layer 325. In this embodiment, solder balls (or solder bumps) 330 are provided on the exposed portion of the ohmic contact such that precursor 300 may be described as being a “flip-chip”.

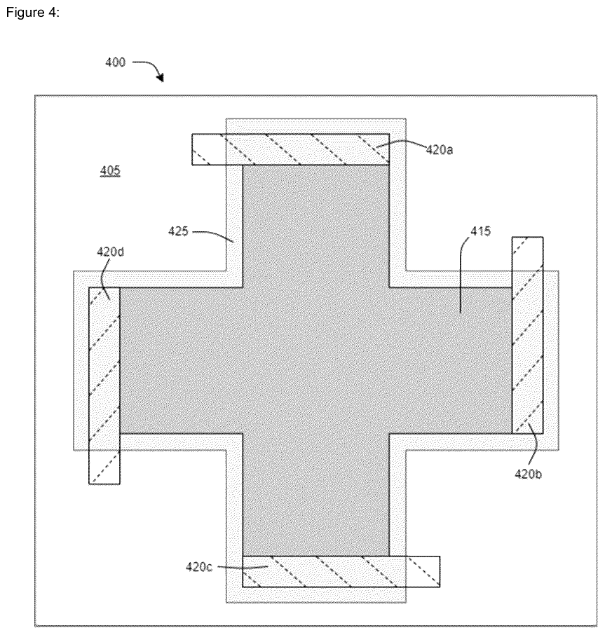

FIG. 4 is a plan view of an electronic device precursor 400. Precursor 400 is suitable for a Hall-sensor and is formed of a 2D-material layer beneath an identically shaped/patterned alumina layer 415, specifically a cross-shape, all of which is formed on a silicon substrate 405. The ends of each of the four “arms” of the cross-shaped layer structure (i.e. the distal portion) of the 2D-material and patterned alumina 415 are in direct contact with each of the four titanium contacts (420a, 420b, 420c and 420d). A continuous air-resistant alumina coating 425 is provided over the layer structure and a portion of each of the contacts in a manner sufficient to encapsulate the edges of the underlying 2D-material layer and leave a portion of each of the titanium contacts exposed. Coating layer 425 may be provided by e-beam evaporation. In FIG. 4, coating layer 425 is illustrated as semi-transparent so as to illustrate the presence of the underlying patterned alumina 415. As will be appreciated, the 2D-material layer has the same shape as alumina layer 415. Precursor 400 is an individual component obtainable by dicing a substrate formed of an array of equivalent precursors sharing the common substrate. Precursor 400 is advantageous in the respect since dicing does not involve cutting through the coating layer 425 since the coating layer does not extend into the so-called “streets” or the portions of the substrate between the array of components being manufactured.

The present inventors have used Raman spectra obtained at various positions of the device precursor to confirm the presence (and quality) or absence of graphene. In particular, the method of the present invention facilitates the clean etching of graphene up to the edge of the patterned alumina such that ohmic contacts may then be provided without having to remove the protective alumina layer. Further, the Raman spectra of the graphene demonstrates that the quality of the graphene proximal to the edge may remain comparable with the quality of the remainder of the underlying and protected portions of graphene (such as at the point of label 415 for the stack of graphene and patterned alumina in FIG. 4). Additionally, the present inventors have used Raman spectroscopy to demonstrate the absence of graphene outside the patterned dielectric between the coating layer and substrate (such as at the point of label 425 for the coating layer in FIG. 4).

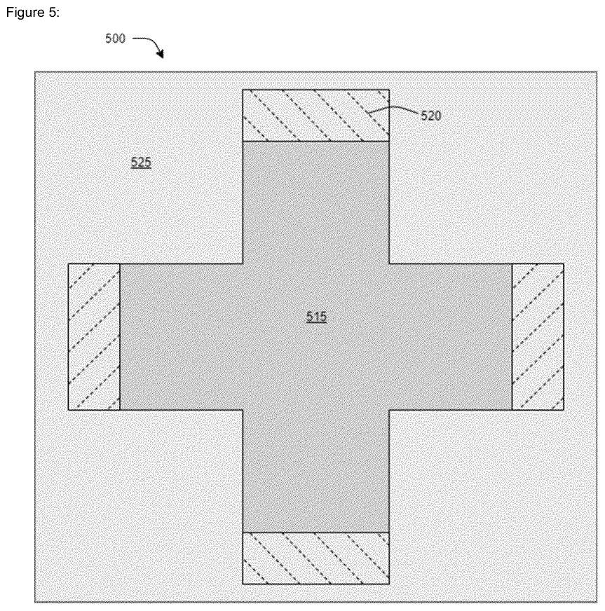

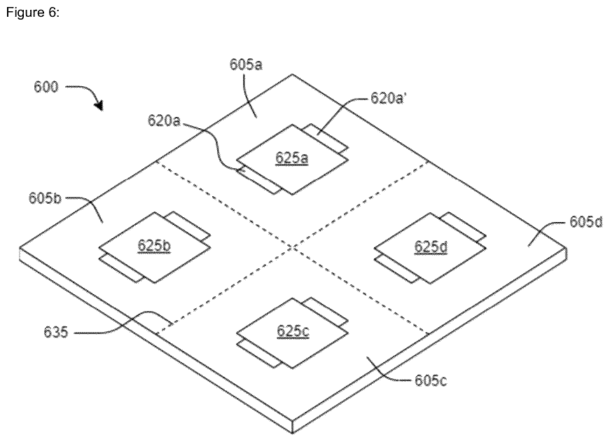

FIG. 5 is a plan view of an electronic device precursor 500. The precursor 500 is suitable for a Hall-sensor and is formed of a 2D-material layer beneath an identically shaped/patterned alumina layer 515, specifically a cross-shape, all of which is formed on a sapphire substrate. Separate gold contacts 520 are provided in direct contact with corresponding edge portions of the underlying 2D-material layer at four portions of the cross, specifically four distal portions which are the ends of each arm of the cross-shape. A continuous air-resistant coating 525 of silica formed by ALD is coated across the entire substrate and the layer structure of the 2D-material and alumina 515 (and therefore all of the edges not in direct contact with the contacts 520) along with all of the contacts 520 themselves. As with FIG. 4, coating layer 525 is illustrated as semi-transparent so as to illustrate the presence of the underlying patterned alumina 515.

FIG. 6 is a perspective view of an array 600 of electronic device precursors. Array 600 is formed of four electronic device precursors which may be separated by dicing the substrate along the streets 635. Each precursor comprises a portion of the substrate (605a, 605b, 605c and 605d) and formed on each portion is coating layer (625a, 625b, 625c and 625d) which encapsulates layer structures of 2D-materials and patterned dielectric layers. Further, each precursor comprises two ohmic contacts (620a and 620a′), portions of which are not encapsulated by the coating layer (625a).

### EXAMPLES

### According to a First Example

1. Graphene was grown on a sapphire substrate according to the process in WO2017/029470.
2. Al₂O₃ was evaporated onto the graphene using thermal evaporation through a shadow mask with apertures in the shape of a cross. The thickness of the evaporated Al₂O₃ was 10 nm.
3. The graphene in areas where it remained exposed as the uppermost layer was removed via plasma etching. The settings used for this were 40% power (on a 100 W device) with 6 sccm oxygen flow rate for 30 s.
4. Ti/Au bar-shaped contacts were evaporated onto the ends of the arms of the cross using another shadow mask. These were made by evaporating 10 nm of Ti and then 120 nm of Au. They were positioned with respect to the cross arms so that they made contact to the edge of the graphene at the ends of the cross arms and extended sideways away from the cross arms.
5. A second layer of evaporated Al₂O₃ was deposited over the first in a cross shape larger than the first, such that it covered the first cross and left part of each bar contact exposed.
6. This gave devices on-wafer, which were then processed via standard BEOL processing.

According to a second example:
1. Graphene was grown on a sapphire substrate according to the process in WO2017/029470.
2. Al₂O₃ was evaporated onto the graphene using thermal evaporation through a shadow mask with apertures in the shape of a cross. The thickness of the evaporated Al₂O₃ was 10 nm.
3. The graphene in areas where it remained exposed as the uppermost layer was removed via plasma etching. The settings used for this were 40% power (on a 100 W device) with 6 sccm oxygen flow rate for 30 s.
4. Ti/Au bar-shaped contacts were evaporated onto the ends of the arms of the cross using another shadow mask. These were made by evaporating 10 nm of Ti and then 120 nm of Au. They were positioned with respect to the cross arms so that they made contact to the edge of the graphene at the ends of the cross arms and extended sideways away from the cross arms.
5. A second layer of Al₂O₃ was deposited over the entire wafer using ALD. This layer was 65 nm thick.
6. This gave devices on-wafer, which were then processed via standard BEOL processing.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “below”, “beneath”, “lower”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method of producing an electronic device precursor, the method comprising:
(i) providing a plasma-etchable layer structure on a plasma-resistant substrate, wherein the layer structure has an exposed upper surface;
(ii) patterning a plasma-resistant dielectric by physical vapour deposition onto the exposed upper surface to form an intermediate having at least one covered region and at least one uncovered region of the layer structure;
(iii) subjecting the intermediate to plasma etching, whereby the at least one uncovered region of the layer structure is etched away to form at least one covered region of the layer structure having an exposed edge surface;
(iv) forming an ohmic contact in direct contact with a portion of the exposed edge surface;
wherein the plasma-etchable layer structure comprises one or more graphene layers which extend across the covered regions of the layer structure to the exposed edge surface; and
wherein, either before or after step (iv), the method further comprises (v) forming a coating layer to provide the covered region of the layer structure with a continuous air-resistant coating.

2. The method according to claim 1, wherein the plasma-resistant substrate is sapphire, silicon, silicon dioxide, silicon nitride, silicon carbide, germanium, or a III-V semiconductor.

3. The method according to claim 1, wherein the plasma-resistant dielectric and/or the coating layer are each an inorganic oxide, nitride, carbide, fluoride or sulphide.

4. The method according to claim 1, wherein the plasma etching comprises oxygen plasma etching.

5. The method according to claim 1, wherein the plasma-etchable layer structure consists of one or more 2D-material layers.

6. The method according to claim 5, wherein the plasma-etchable layer structure consists of one or more graphene layers and, optionally, one or more layers of silicene, germanene, h-BN, borophene and/or a TMDC.

7. The method according to claim 6, wherein the one or more graphene layers and, where present, the one or more layers of silicene, germanene, h-BN, borophene and/or a TMDC, are each formed by CVD or MOCVD.

8. The method according to claim 1, wherein step (ii) comprises forming:
(a) one or more rectangular-shaped regions of the plasma-resistant dielectric and wherein the electronic device precursor is for forming a transistor; or
(b) one or more cross-shaped regions of the plasma-resistant dielectric and wherein the electronic device precursor is for forming a Hall-sensor.

9. The method according to claim 1, wherein step (ii) comprises patterning a plasma-resistant dielectric by e-beam evaporation.

10. The method according to claim 1, wherein the method comprises forming an array of covered regions, each corresponding to an electronic device precursor.

11. (canceled)

12. (canceled)

13. (canceled)

14. The method according to claim 1, wherein:
step (v) is performed after step (iv) and the ohmic contact is formed on the plasma-resistant substrate; and
wherein the coating layer is formed by ALD across the plasma-resistant substrate to provide the at least one covered region of the layer structure, the ohmic contact, and remaining exposed edge surface with a continuous air-resistant coating.

15. The method according to claim 14, wherein the method further comprises wire bonding the ohmic contact of the device precursor through the coating layer.

16. The method according to claim 1, wherein:
step (v) is performed after step (iv) and the ohmic contact is formed on the plasma-resistant substrate; and
wherein the coating layer is formed by patterning a coating layer onto the plasma-resistant substrate to provide the at least one covered region of the layer structure and remaining exposed edge surface with a continuous air-resistant coating.

17. The method according to claim 16, wherein the coating layer is formed by e-beam evaporation.

18. The method according to claim 1, wherein:
step (v) is performed before step (iv) and comprises selectively etching away one or more portions of the coating layer to expose corresponding portions of the edge surface, and step (iv) comprises forming an ohmic contact in direct contact with each exposed portion of the edge surface.

19. The method according to claim 18, wherein the selective etching is performed by laser etching or reactive ion etching.

20. The method according to claim 16, wherein the method further comprises depositing a solder bump on the ohmic contact or wire bonding the ohmic contact.

21. An electronic device precursor comprising:
a substrate having a layer structure thereon, the layer structure comprising:
a lower layer on a first region of the substrate, wherein the lower layer comprises one or more graphene layers which extend across the lower layer, and
an upper layer on the lower layer and formed of a dielectric material,
wherein the lower and upper layers share a continuous outer edge surface,
an ohmic contact provided on a further region of the substrate and in direct contact with the one or more graphene layers via the continuous outer edge surface, and
a continuous air-resistant coating layer either (a) across the substrate, the layer structure, and the at least one ohmic contact or (b) enclosing the layer structure.

22. (canceled)

23. (canceled)

24. (canceled)

25. The electronic device precursor according to claim 21, wherein the lower layer further comprises one or more layers of silicene, germanene, h-BN, borophene and/or a TMDC which extend across the lower layer.

26. The electronic device precursor according to claim 21, wherein the electronic device precursor is for forming a Hall-sensor, and wherein the charge carrier density of the one or more graphene layers is less than 8×10¹¹ cm⁻².
